(19) United States
(12) Patent Application Publication
(10) Pub. No.: US 2026/0177582 A1
(43) Pub. Date: Jun. 25, 2026

(54) TEST PROBE AND TEST DEVICE

(71) Applicant: LEENO INDUSTRIAL INC., Busan (KR)

(72) Inventors: Seungha BAEK, Busan (KR); Minju LIM, Busan (KR); Changwook KIM, Busan (KR); Chaeyoon LEE, Busan (KR)

(73) Assignee: LEENO INDUSTRIAL INC., Busan (KR)

(21) Appl. No.: 18/849,200

(22) PCT Filed: Apr. 2, 2024
(86) PCT No.: PCT/KR2024/004264

§ 371 Date: Sep. 20, 2024

(30) Foreign Application Priority Data
Apr. 26, 2023 (KR) 10-2023-0054922
Dec. 4, 2023 (KR) 10-2023-0173347

(51) Int. Cl. G01R 1/067

(52) U.S. Cl. CPC G01R 1/06722; G01R 1/06733

(57) ABSTRACT

Disclosed is a test probe including barrel including tubular barrel main body, and skirt portions separated from each other by slits formed in first end portion of barrel main body in lengthwise direction; and plunger including sliding portion accommodated in barrel main body and sliding along lengthwise direction of barrel, and terminal contact portion extending from the sliding portion along lengthwise direction and exposed beyond skirt portion. Skirt portion includes skirt main body extending in lengthwise direction of barrel main body, and skirt diameter-reducing portion curved reducing diameter thereof in fore-end area of skirt main body in lengthwise direction of barrel and including facing end portion to face surface of terminal contact portion. Sliding portion includes small diameter portion positioned in skirt main body and having a first diameter, and a large diameter portion positioned in the barrel main body and having a second diameter larger than the first diameter.

### TECHNICAL FIELD

The disclosure relates to a test probe and a test device for testing the electrical characteristics of a semiconductor or the like subject-to-be-tested.

### BACKGROUND ART

FIG. 1 is a view showing a conventional test probe 10.

Referring to FIG. 1, a test probe 10 includes a cylindrical barrel 11, a plunger 12 coupled to and slidable within one side of the barrel 11, a terminal 13 secured to the other side of the barrel 11, and a spring 14 inserted between the plunger 12 and the terminal 13 in the barrel 11 and providing elasticity.

A test signal may be transmitted from the plunger 12 to the terminal 13 via the barrel 11 and the spring 14. In more detail, the test signal applied to the plunger 12 is transmitted to the terminal 13 secured to a second end portion of the barrel 11 via a first end portion of the barrel 11, the inner wall of the barrel 11 and the spring 14. In this case, the plunger 12 and the barrel 11 is required to maintain an appropriate gap therebetween for the smooth sliding of the plunger 12. Such a gap causes unstable contact during a test, and results in unstable resistance as shown in FIG. 2, thereby leading to a problem of misjudging a good subject-to-be-tested as a defective product.

Further, the end of the barrel is closed to prevent the plunger from falling out while sliding. During the test, the plunger slides and provides a large load to the sharp end of the barrel, thereby causing a problem that a plating portion coated on the outer surface of the plunger is damaged.

### DISCLOSURE

### Technical Problem

*6An aspect of the disclosure is to provide a test probe and a test device, in which a stable signal transmission path is ensured during a test, thereby increasing the reliability of the test.

Another aspect of the disclosure is to provide a test probe and a test device, which are excellent in durability.

### Technical Solution

According to an embodiment of the disclosure, there is provided a test probe. The test probe includes: a barrel including a tubular barrel main body, and a plurality of skirt portions separated from each other by a plurality of slits formed in a first end portion of the barrel main body in a lengthwise direction; and a plunger including a sliding portion accommodated in the barrel main body and sliding along the lengthwise direction of the barrel, and a terminal contact portion extending from the sliding portion along the lengthwise direction and exposed beyond the skirt portion. The skirt portion includes a skirt main body extending in the lengthwise direction of the barrel main body, and a skirt diameter-reducing portion curved reducing a diameter thereof in a fore-end area of the skirt main body in the lengthwise direction of the barrel and including a facing end portion to face a surface of the terminal contact portion. The sliding portion includes a small diameter portion positioned in the skirt main body and having a first diameter, and a large diameter portion positioned in the barrel main body and having a second diameter larger than the first diameter.

The plunger may include a slope contact portion provided between the sliding portion and the terminal contact portion to come into contact with an inner surface of the skirt diameter-reducing portion. The inner surface of the skirt diameter-reducing portion may have a different linear slope from an outer surface of the slope contact portion. Thus, a contact area between the inner surface of the skirt diameter-reducing portion and the outer surface of the slope contact portion is minimized to reduce damage of an external plating layer of the slope contact portion due to burs at the inner edge of the skirt diameter-reducing portion.

The plunger my include a slope contact portion provided between the sliding portion and the terminal contact portion to come into contact with an inner surface of the skirt diameter-reducing portion. The inner surface of the skirt diameter-reducing portion may have a different curvature from an outer surface of the slope contact portion. Thus, a contact area between the inner surface of the skirt diameter-reducing portion and the outer surface of the slope contact portion is minimized to reduce damage of an external plating layer of the slope contact portion due to burs at the inner edge of the skirt diameter-reducing portion.

The plunger may include a slope contact portion provided between the sliding portion and the terminal contact portion to come into contact with an inner surface of the skirt diameter-reducing portion. One of the inner surface of the skirt diameter-reducing portion and an outer surface of the slope contact portion may have a slope surface having a predetermined linear slope. The other one of the inner surface of the skirt diameter-reducing portion and the outer surface of the slope contact portion may have a curved surface having a predetermined curvature. Thus, a contact area between the inner surface of the skirt diameter-reducing portion and the outer surface of the slope contact portion is minimized to reduce damage of an external plating layer of the slope contact portion due to burs at the inner edge of the skirt diameter-reducing portion.

The terminal contact portion may include a tapering portion, a diameter of which decreases in a direction toward the sliding portion, in at least a partial section thereof. Thus, the durability of the skirt portion is increased.

The terminal contact portion may include an extending bar extending from the tapering portion to an opposite side of the sliding portion, and having a uniform diameter. Thus, the skirt portion is formed only in a portion being in contact with the facing end portion, and the other portions are formed to have a uniform diameter, thereby increasing the durability of the terminal contact portion.

The terminal contact portion may include a tip to come into contact with a terminal of a subject-to-be-tested, and a tapering portion having a diameter increasing in a direction from the tip toward the sliding portion. Thus, the contact between the terminal contact portion and the facing end portion of the skirt portion is reduced to increase the durability of the skirt portion.

### Advantageous Effects

According to an embodiment of the disclosure, the test probe includes a barrel main body, and a plurality of skirt portions separated by slits formed in an end portion of the barrel main body on one side thereof in a lengthwise direction and having a diameter reduced toward a central axis. Because the inner surface of the fore-end area of each skirt portion is in contact with the outer surface of the plunger throughout a predetermined lengthwise section, the stable contact between the plunger and the barrel is maintained during the test, thereby improving the reliability of the test. Further, when a large load is applied to the end portion of the barrel during the sliding operation of the plunger, the skirt portions are opened outwardly in the radial direction, thereby preventing the plating portion of the plunger from being damaged due to the load.

The skirt portions may have low durability because they are separated by the slits. Therefore, the facing length of the facing end portion in the axial-line direction, which is in contact with the plunger, is greater than the thickness of the skirt diameter-reducing portion or the skirt main body, thereby increasing the durability and securing the length for the chamfering of the fore-end edge.

The fore-end edge of the skirt diameter-reducing portion is chamfered to prevent the outer surface of the plunger from being scratched.

### DESCRIPTION OF DRAWINGS

FIG. 1 is a view showing a conventional test probe.

FIG. 2 is a view showing distribution of resistance measured during a test using a conventional test probe.

FIG. 3 is a perspective view of a test probe according to a first embodiment of the disclosure.

FIG. 4 is a cross-sectional view of the test probe taken along line A-A of FIG. 3.

FIG. 5 is a view showing a contact state between a skirt portion and a terminal contact portion of a plunger in FIG. 3.

FIG. 6 is a view showing a test probe according to a second embodiment of the disclosure.

FIG. 7 is a view showing a test probe according to a third embodiment of the disclosure.

FIG. 8 is a view showing a barrel of a test probe according to a fourth embodiment of the disclosure.

FIG. 9 is a view showing a barrel of a test probe according to a fifth embodiment of the disclosure.

FIG. 10 is a view showing a test probe according to a sixth embodiment of the disclosure.

FIG. 11 is a view showing a test probe according to a seventh embodiment of the disclosure.

FIG. 12 is a view showing a test probe according to an eighth embodiment of the disclosure.

FIG. 13 is a schematic diagram showing a method of manufacturing a barrel of FIG. 3.

FIG. 14 is a schematic diagram showing a method of manufacturing a barrel of FIG. 6.

FIG. 15 is a schematic diagram showing a method of manufacturing a barrel of FIG. 7.

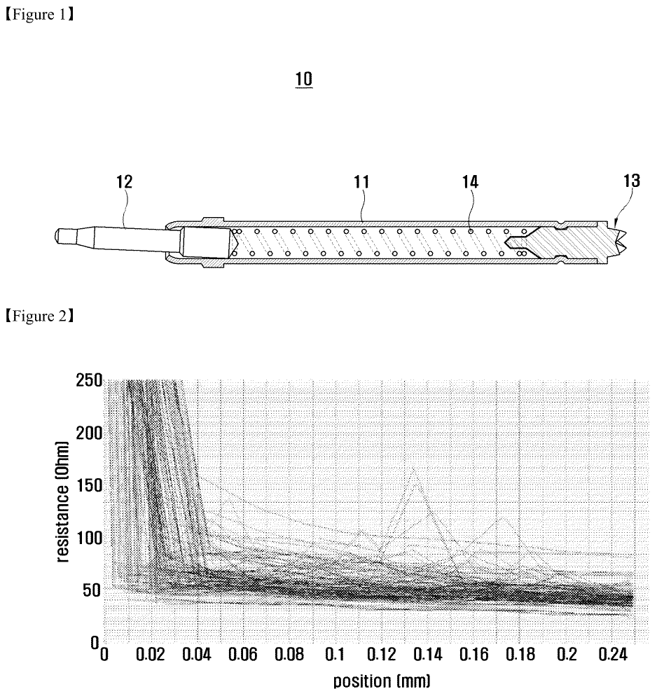

### BEST MODE

Below, a test probe 100 according to embodiments of the disclosure will be described in detail with reference to the accompanying drawings.

For example, a test device for testing the electrical characteristics of a semiconductor or the like subject-to-be-tested includes probe supporters (not shown) shaped like plates, and a test probe 100 supported between the top and bottom surfaces of the probe supporter so that both end portions thereof can partially protrude from the top and bottom surfaces of the probe supporter.

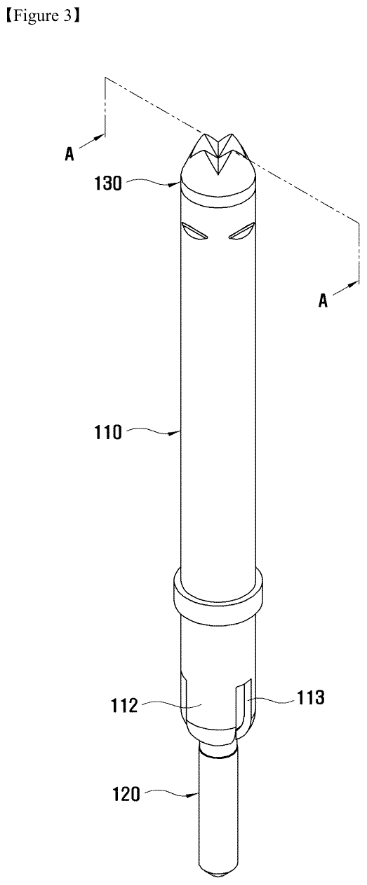

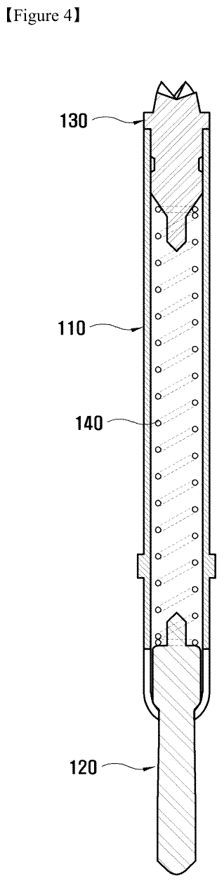

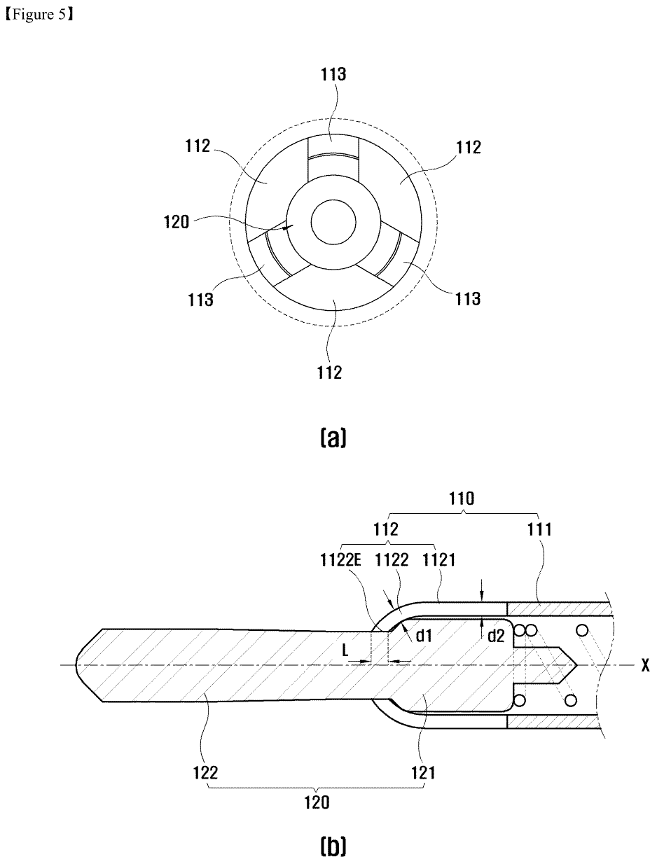

FIG. 3 is a perspective view of a test probe 100 according to a first embodiment of the disclosure, FIG. 4 is a cross-sectional view of the test probe 100 taken along line A-A of FIG. 3, and FIG. 5 is a view showing a contact state between a skirt portion 112 and a terminal contact portion 122 of a plunger 120 in FIG. 3.

Referring to FIGS. 3 to 5, the test probe 100 includes, for example, a cylindrical barrel 110, a plunger 120 coupled to and slidable within a first side of the barrel 110, a terminal 130 secured to a second side of the barrel 110, and an elastic body 140 interposed between the plunger 120 and the terminal 130 in the barrel 110 and providing elasticity.

The barrel 110 includes a barrel main body 111, and a skirt portion 112 separated by a plurality of slits 113 formed at predetermined intervals along the circumferential direction at a first end portion where the plunger 120 is inserted. The number of slits 113 is not limited to three, and may be two or four or more. The slits 113 may extend diagonally or spirally with respect to the lengthwise direction of the test probe 100. The slits 113 may be cut having a uniform width.

The plunger 120 may include a sliding portion 121 accommodated and sliding in the barrel main body 111, and a terminal contact portion 122 extending from the sliding portion 121, exposed to the outside through the skirt portion 112, and being in contact with the skirt portion 112.

The sliding portion 121 has a diameter corresponding to the inner diameter of the barrel main body 111. The diameter of the sliding portion 121 is set to be smaller than the barrel main body 111 so as to slide within the barrel main body 111.

The terminal contact portion 122 has a diameter smaller than the diameter of the sliding portion 121. The diameter of the terminal contact portion 122 is set to such an extent that the terminal contact portion 122 can pass facing a fore-end of the skirt portion 112. The end portion of the terminal contact portion 122 comes into contact with the terminal 310 (not shown).

The terminal 130 fixedly secured to a second end portion of the barrel 110 by dimpling or caulking. Alternatively, the terminal 130 may be inserted to be slidable rather than fixed.

The elastic body 140 is compressed and restored as the plunger 120 moves sliding during a test. The elastic body 140 may for example be implemented by a coil spring.

Referring to FIG. 5, the skirt portion 112 includes a skirt main body 1121 extending along the barrel main body 111, and a skirt diameter-reducing portion 1122 curved reducing its diameter in an axial-line direction X of the barrel 110 in a fore-end area of the skirt main body 1121.

The skirt main body 1121 extends parallel having the same thickness as the barrel main body 111.

The skirt diameter-reducing portion 1122 has a facing end portion 1122E provided in the fore-end area and facing the surface of the terminal contact portion 122. The facing length L of the facing end portion 1122E in the axial-line direction X is greater than the thickness d1 of the skirt diameter-reducing portion 1122 and/or the thickness d2 of the skirt main body 1121. The thickness d1 of the skirt diameter-reducing portion 1122 is substantially the same as the thickness d2 of the skirt main body 1121.

The inner diameter of the facing end portion 1122E may be formed by cylindrical cutting along the axial-line direction X of the barrel.

The fore-end edge of the skirt diameter-reducing portion 1122 may have a chamfered portion. As the facing length L in the axial-line direction X is greater than the thickness d1 of the skirt diameter-reducing portion 1122 and/or the thickness d2 of the skirt main body 1121, the fore-end edge of the skirt diameter-reducing portion 1122 may be subjected to chamfering. If the fore-end edge of the skirt diameter-reducing portion 1122 is chamfered without sufficiently securing the facing length L in the axial-line direction X, the facing end portion 1122E becomes sharp and scratches and peels off the plating portion on the surface of the terminal contact portion 122 during the test.

Further, when the test probe 100 is pressed during the test, the terminal contact portion 122 may be tilted at an angle. In this case, if the skirt portion 112 is absent, strong friction may occur between the terminal contact portion 122 and the fore-end portion of the barrel 110, thereby scratching and peeling off the surface of the terminal contact portion 122. On the other hand, according to an embodiment, the skirt portion 112 is transformed in a radial direction, thereby alleviating the friction between the terminal contact portion 122 and the fore-end portion of the barrel 110.

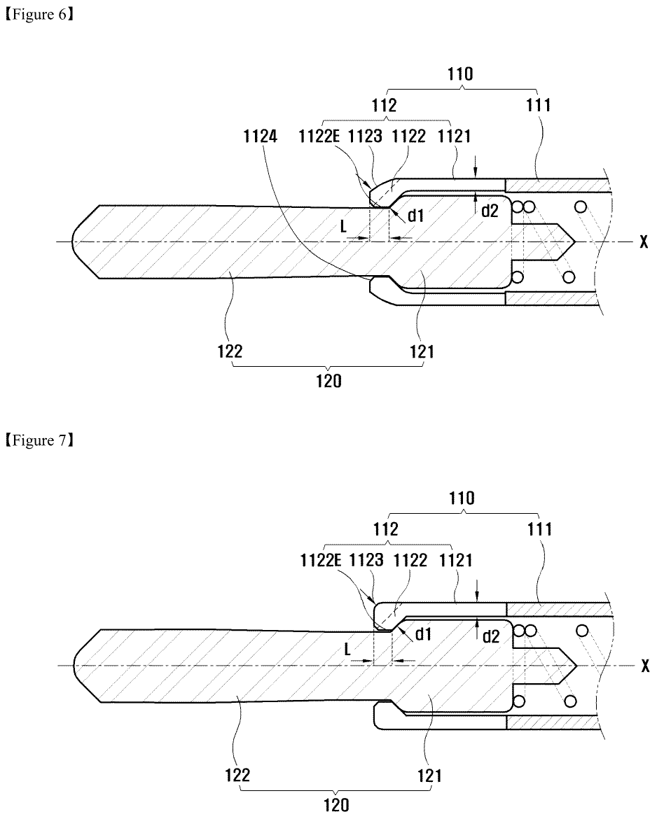

FIG. 6 is a view showing a test probe according to a second embodiment of the disclosure.

Referring to FIG. 6, a skirt portion 112 includes a skirt main body 1121, and a skirt diameter-reducing portion 1122 curved from the skirt main body 1121 to reduce its diameter in the axial-line direction X of the barrel 110.

The skirt main body 1121 substantially extended in the lengthwise direction of the barrel main body 111.

The skirt diameter-reducing portion 1122 includes a thick portion 1123 provided in an area facing the terminal contact portion 122 and expanding outwardly in the radial direction. The thick portion 1123 expands to gradually become thicker along the axial-line direction X of the barrel 110. Due to the thick portion 1123, the thickness d1 of the skirt diameter-reducing portion 1122 is greater than the thickness d2 of the skirt main body 1121. The thick portion 1123 may be formed by extrusion.

The fore-end edge of the skirt diameter-reducing portion 1122 has a chamfered portion 1124. The thick portion 1123 expands the facing length L of the facing end portion 1122E being in contact with the terminal contact portion 122, and the chamfered portion 1124 shortens the facing length L to prevent the facing end portion 1122E from becoming sharp.

FIG. 7 is a view showing a test probe 100 according to a third embodiment of the disclosure.

Referring to FIG. 7, a skirt portion 112 includes a skirt main body 1121, and a skirt diameter-reducing portion 1122 curved from the skirt main body 1121 to reduce its diameter in the axial-line direction X of the barrel 110.

The skirt diameter-reducing portion 1122 includes a thick portion 1123 expanding outwardly in a radial direction in an area facing the terminal contact portion 122. The thick portion 1123 is formed to gradually become thicker and then become thinner along the lengthwise direction of the barrel 110. In other words, the outer surface of the thick portion 1123 extends along the lengthwise direction of the skirt main body 1121 and then extends in a transverse direction substantially perpendicular to the lengthwise direction.

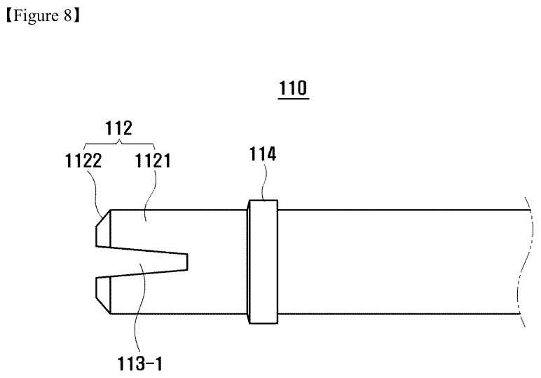

FIG. 8 is a view showing a barrel 110 of a test probe according to a fourth embodiment of the disclosure

Referring to FIG. 8, the barrel 110 includes a skirt portion 112 formed by a slit 113-1. The slit 113-1 has a tapering shape that tapers toward a flange 114. The slit 113-1 having the tapering shape is easier to machine than the slit 113 having the uniform width as shown in FIG. 3, and reduces burs remaining at the inner edge of the skirt portion 112.

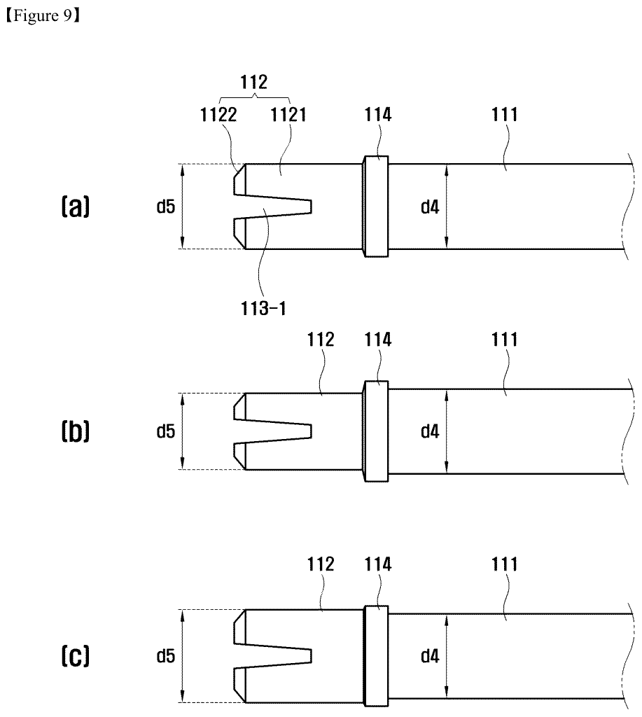

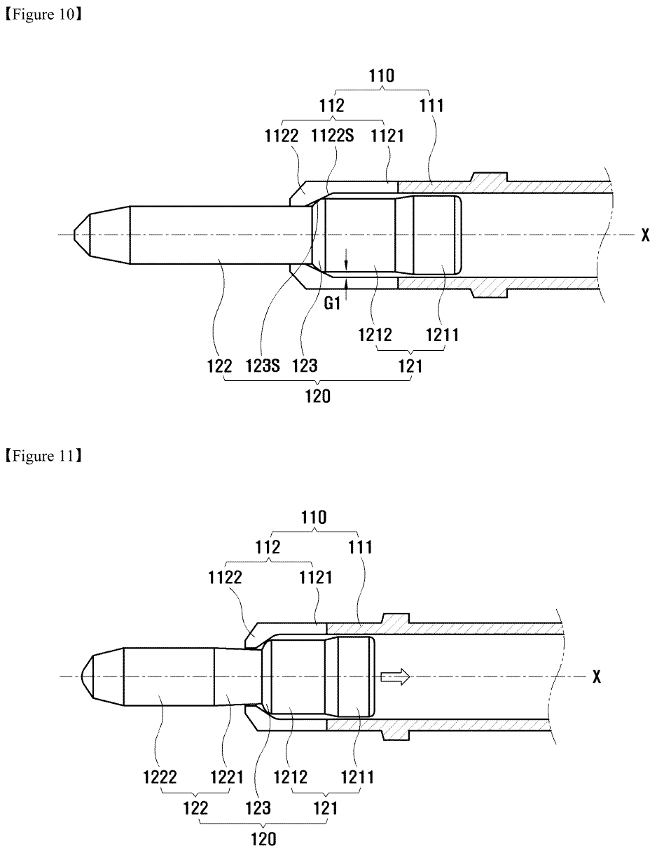

FIG. 9 is a view showing a barrel 110 of a test probe according to a fifth embodiment of the disclosure.

Referring to FIG. 9, the barrel 110 includes a skirt portion 112 formed by a slit 113-1. The skirt portion 112 may be formed to be different in thickness to adjust elasticity in a radial direction.

As shown in (a) of FIG. 9, the skirt main body 1121 may have an outer diameter d5 equal to an outer diameter d4 of the barrel main body 111. In this case, the skirt main body 1121 and the barrel main body 111 have the same inner diameter.

As shown in (b) of FIG. 9, the skirt main body 1121 may have the outer diameter d5 smaller than the outer diameter d4 of the barrel main body 111. In other words, the skirt portion 112 may become thinner by cutting the outer diameter on the left side with respect to the flange 114. In this case, the skirt main body 1121 and the barrel main body 111 have the same inner diameter. When the skirt main body 1121 is thin, the elasticity of the skirt portion 112 in the radial direction is decreased.

As shown in (c) of FIG. 9, the skirt main body 1121 may be machined to have the outer diameter d5 larger than the outer diameter d4 of the barrel main body 111. In other words, the skirt portion 112 may become thicker by cutting the outer diameter on the right side with respect to the flange 114. In this case, the skirt main body 1121 and the barrel main body 111 have the same inner diameter. When the skirt main body 1121 is thick, the elasticity of the skirt portion 112 in the radial direction is increased.

FIG. 10 is a view showing a test probe 100 according to a sixth embodiment of the disclosure

Referring to FIG. 10, the barrel 110 includes a skirt portion 112 formed by a slit extending in a lengthwise direction at an end portion on a first side. The skirt portion 112 includes a skirt main body 1121 extending from a barrel main body 111 in the lengthwise direction, and a skirt diameter-reducing portion 1122 curved from the skirt main body 1121 to reduce its diameter in the axial-line direction X of the barrel main body 111.

A plunger 120 includes a sliding portion 121 inserted in the barrel main body 111 and sliding, a terminal contact portion 122 exposed to the outside while passing through the fore-end portion of the skirt portion 112 from the sliding portion 121 and coming into contact with the terminal of a subject-to-be-tested, and a slope contact portion 123 formed between the sliding portion 121 and the terminal contact portion 122.

The sliding portion 121 includes a large diameter portion 1211 having an outer diameter to be almost adjacent to the inner surface of the barrel main body 111, and a small diameter portion 1212 having an outer diameter to form a predetermined gap G1 from the inner surface of the skirt portion 112. The gap G1 formed by the small diameter portion 1212 prevents the movement of the sliding portion 121 from being hindered by burs remaining at the inner edge of the skirt portion 112, and prevents the surface of the sliding portion from being scratched.

The skirt diameter-reducing portion 1122 has an inner slope surface 1122S having a predetermined linear slope, and the slope contact portion 123 has an outer slope surface 123S having a predetermined curvature. As a result, the inner slope surface 1122S and the outer slope surface 123S are in contact with each other through a minimum area. Thus, the outer slope surface 123S of the slope contact portion 123 is prevented from being damaged by the burs remaining at the inner edge of the skirt diameter-reducing portion 1122.

According to an alternative embodiment, the skirt diameter-reducing portion 1122 may have an inner slope surface 1122S having a predetermined curvature, and the slope contact portion 123 may have an outer slope surface 123S having a predetermined linear slope.

According to an alternative embodiment, the skirt diameter-reducing portion 1122 may have an inner slope surface 1122S having a first linear slope, and the slope contact portion 123 may have an outer slope surface 123S having a second linear slope different from the first linear slope.

According to an alternative embodiment, the skirt diameter-reducing portion 1122 may have an inner slope surface 1122S having a first curvature, and the slope contact portion 123 may have an outer slope surface 123S having a second curvature different from the first curvature.

FIG. 11 is a view showing a test probe 100 according to a seventh embodiment of the disclosure.

Referring to FIG. 11, the barrel 110 includes a skirt portion 112 formed by a slit extending in a lengthwise direction at an end portion on a first side. The skirt portion 112 includes a skirt main body 1121 extending from a barrel main body 111 in the lengthwise direction, and a skirt diameter-reducing portion 1122 curved from the skirt main body 1121 to reduce its diameter in the axial-line direction X of the barrel main body 111.

A plunger 120 includes a sliding portion 121 inserted in the barrel main body 111 and sliding, a terminal contact portion 122 exposed to the outside while passing through the fore-end portion of the skirt portion 112 from the sliding portion 121 and coming into contact with the terminal of a subject-to-be-tested, and a slope contact portion 123 formed between the sliding portion 121 and the terminal contact portion 122.

The terminal contact portion 122 includes a first tapering portion 1221, the outer diameter of which gradually decreases toward the slope contact portion 123 within at least a partial section. Before the plunger 120 slides in the arrow direction for the test, the first tapering portion 1221 may not be in contact with the facing end portion 1122E provided at the fore-end of the skirt diameter-reducing portion 1122 or may be in contact with the facing end portion 1122E by a minimum contact force. When the plunger 120 slides in the arrow direction for the test, the first tapering portion 1221 may be in contact with the facing end portion 1122E of the skirt diameter-reducing portion 1122 by a stronger contact force. Thus, the skirt portion 112 is prevented from elastic deterioration due to constant pressure of the facing end portion 1122E of the skirt portion 112 against the terminal contact portion 122 in a standby state in which the test is not being performed.

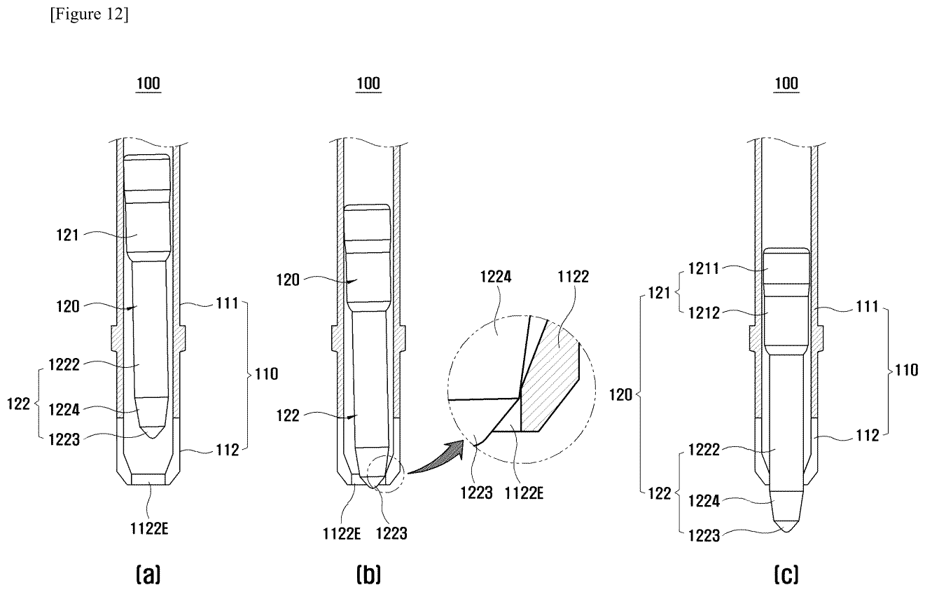

FIG. 12 is a view showing a test probe 100 according to an eighth embodiment of the disclosure.

Referring to (a) of FIG. 12, the barrel 110 includes a skirt portion 112 formed by a slit extending in a lengthwise direction at an end portion on a first side.

A plunger 120 includes a sliding portion 121 inserted in the barrel main body 111 and sliding, and a terminal contact portion 122 exposed to the outside while passing through the facing end portion 1122E of the skirt portion 112 from the sliding portion 121.

The terminal contact portion 122 includes an extending bar 1222 extending integrally from the sliding portion 121, a tip 1223 coming into contact with the terminal of a subject-to-be-tested, and a second tapering portion 1224 provided between the extending bar 1222 and the tip 1223. The second tapering portion 1224 obliquely extends to have a diameter gradually decreasing toward the tip 1223.

The plunger 120 is exposed to the outside as shown in (c) of FIG. 12 as the terminal contact portion 122 passes through the facing end portion 1122E of the skirt portion 112 as shown in (b) of FIG. 12. In this case, when the terminal contact portion 122 collides with and applies an impact to the inner surface of the skirt portion 112, the skirt portion 112 may be deformed. To prevent the deformation of the skirt portion 112, the second tapering portion 1224 having a predetermined slope is provided adjacent to the tip 1223. Thus, the skirt portion 112 is prevented from being deformed due to the contact and pressure of the terminal contact portion 122 against the inner surface of the skirt portion 112.

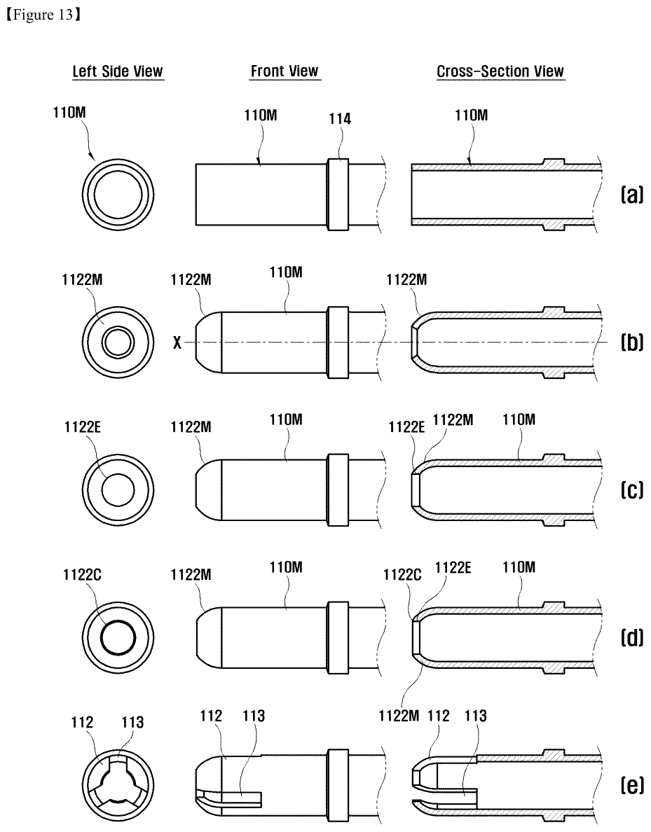

FIG. 13 is a schematic diagram showing a method of manufacturing a barrel 110 of FIG. 3.

In a first step, as shown in (a) of FIG. 13, a cylindrical pipe member 110M is formed of a conductive material. The pipe member 110M may include a flange 114.

In a second step, as shown in (b) of FIG. 13, a diameter-reducing portion 1122M is formed at one end portion of the pipe member 110M by, for example, forging using a mold. The diameter-reducing portion 1122M is shaped to have a diameter decreasing along the axial-line direction X of the pipe member 110M.

In a third step, as shown in (c) of FIG. 13, a facing end portion 1122E is formed on a fore-end surface of the diameter-reducing portion 1122M. The facing end portion 1122E is formed along substantially the lengthwise direction of the pipe member 110M. For example, the facing end portion 1122E may be formed by cylindrically cutting the fore-end inner surface of the diameter-reducing portion 1122M along the axial-line direction X of the barrel through a drill.

In a fourth step, as shown in (d) of FIG. 13, a chamfered portion 1122C is formed at the fore-end edge of the diameter-reducing portion 1122M. The chamfered portion 1122C may be formed by chamfering to have an obtuse angle with respect to the facing end portion 1122E.

In a fifth step, as shown in (e) of FIG. 13, three slits 113 are formed in the diameter-reducing portion 1122M and a portion of the pipe member 110M shown in (d) of FIG. 13 along the lengthwise direction. The three slits 113 are formed at intervals of 120 degrees in a circumferential direction to form three skirt portions 112. The number of slits 113 is not limited to three. The slits 113 may for example be formed by cutting to have a uniform width or to be gradually widened along an open-end portion through a drill.

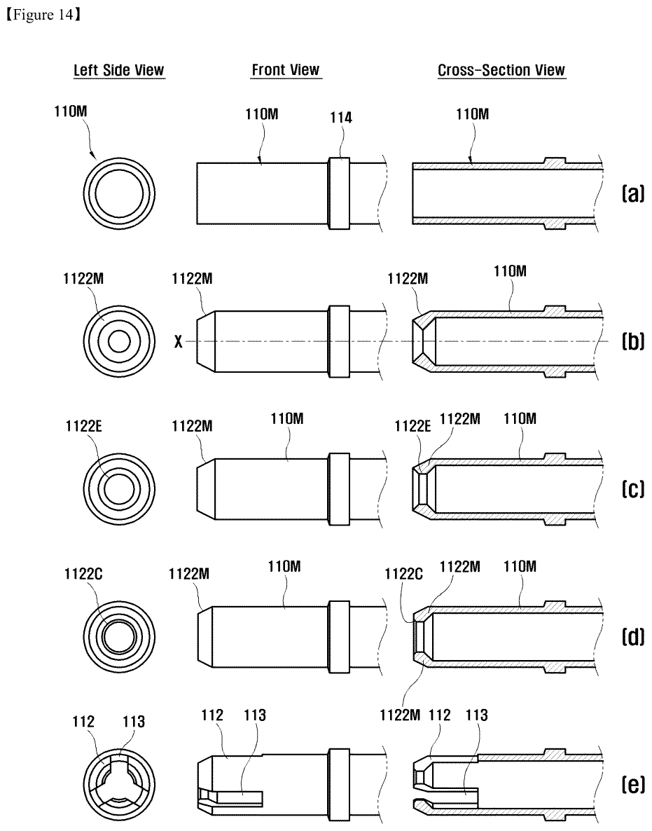

FIG. 14 is a schematic diagram showing a method of manufacturing a barrel 110 of FIG. 6.

In a first step, as shown in (a) of FIG. 14, a cylindrical pipe member 110M is formed of a conductive material. The pipe member 110M may include a flange 114.

In a second step, as shown in (b) of FIG. 14, a diameter-reducing portion 1122M is formed at one end portion of the pipe member 110M by, for example, forging using a mold. The diameter-reducing portion 1122M is shaped to have a diameter decreasing along the axial-line direction X of the pipe member 110M. The diameter-reducing portion 1122M is shaped to have a gradually increasing thickness. The diameter-reducing portion 1122M is thicker than the pipe member 110M.

In a third step, as shown in (c) of FIG. 14, a facing end portion 1122E is formed on a fore-end surface of the diameter-reducing portion 1122M. The facing end portion 1122E is formed along substantially the lengthwise direction of the pipe member 110M. For example, the facing end portion 1122E may be formed by cylindrically cutting the fore-end inner surface of the diameter-reducing portion 1122M along the axial-line direction X of the barrel through a drill.

In a fourth step, as shown in (d) of FIG. 14, a chamfered portion 1122C is formed at the fore-end edge of the diameter-reducing portion 1122M. The chamfered portion 1122C may be formed by chamfering to have an obtuse angle with respect to the facing end portion 1122E.

In a fifth step, as shown in (e) of FIG. 14, three slits 113 are formed in the diameter-reducing portion 1122M and a portion of the pipe member 110M shown in (d) of FIG. 13 along the lengthwise direction. The three slits 113 are formed at intervals of 120 degrees in a circumferential direction to form three skirt portions 112. The number of slits 113 is not limited to three. The slits 113 may for example be formed by cutting to have a uniform width or to be gradually widened along an open-end portion through a drill.

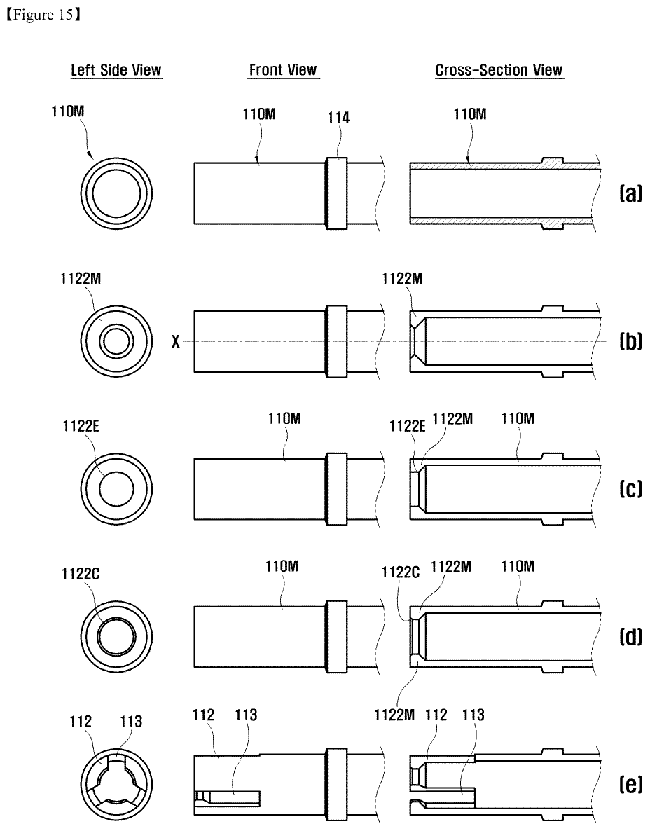

FIG. 15 is a schematic diagram showing a method of manufacturing a barrel 110 of FIG. 7.

In a first step, as shown in (a) of FIG. 15, a cylindrical pipe member 110M is formed of a conductive material. The pipe member 110M may include a flange 114.

In a second step, as shown in (b) of FIG. 15, a diameter-reducing portion 1122M is formed at one end portion of the pipe member 110M by, for example, forging using a mold. The diameter-reducing portion 1122M is shaped to have a diameter decreasing along the axial-line direction X of the pipe member 110M. The thickness of the diameter-reducing portion 1122M is gradually increased and then decreased. The diameter-reducing portion 1122M is thicker than the pipe member 110Ma.

In a third step, as shown in (c) of FIG. 15, a facing end portion 1122E is formed on a fore-end surface of the diameter-reducing portion 1122M. The facing end portion 1122E is formed along substantially the lengthwise direction of the pipe member 110M. For example, the facing end portion 1122E may be formed by cylindrically cutting the fore-end inner surface of the diameter-reducing portion 1122M along the axial-line direction X of the barrel through a drill. The diameter-reducing portion 1122M has a second outer surface substantially perpendicular to a first outer surface substantially parallel to the facing end portion 1122E.

In a fourth step, as shown in (d) of FIG. 15, a chamfered portion 1122C is formed at the fore-end edge of the diameter-reducing portion 1122M. The chamfered portion 1122C may be formed by chamfering to have an obtuse angle with respect to the facing end portion 1122E.

In a fifth step, as shown in (e) of FIG. 15, three slits 113 are formed in the diameter-reducing portion 1122M and a portion of the pipe member 110M shown in (d) of FIG. 13 along the lengthwise direction. The three slits 113 are formed at intervals of 120 degrees in a circumferential direction to form three skirt portions 112. The number of slits 113 is not limited to three. The slits 113 may for example be formed by cutting to have a uniform width or to be gradually widened along an open-end portion through a drill.

According to an embodiment of the disclosure, the test probe includes a barrel main body, and a plurality of skirt portions separated by slits formed in an end portion of the barrel main body on one side thereof in a lengthwise direction and having a diameter reduced toward a central axis. Because the inner surface of the fore-end area of each skirt portion is in contact with the outer surface of the plunger throughout a predetermined lengthwise section, the stable contact between the plunger and the barrel is maintained during the test, thereby improving the reliability of the test. Further, when a large load is applied to the end portion of the barrel during the sliding operation of the plunger, the skirt portions are opened outwardly in the radial direction, thereby preventing the plating portion of the plunger from being damaged due to the load.

The skirt portions may have low durability because they are separated by the slits. Therefore, the facing length of the facing end portion in the axial-line direction, which is in contact with the plunger, is greater than the thickness of the skirt diameter-reducing portion or the skirt main body, thereby increasing the durability and securing the length for the chamfering of the fore-end edge.

The fore-end edge of the skirt diameter-reducing portion is chamfered to prevent the outer surface of the plunger from being scratched.

Although exemplary embodiments of the disclosure have been shown and described, the disclosure is not limited to the foregoing specific embodiments, various alternative modifications can be embodied by a person having an ordinary skill in the art without departing from the scope of the disclosure as claimed in the appended claims, and such modified embodiments should not be understood separately from the technical sprit or prospect of the disclosure.

1. A test probe comprising:
a barrel comprising a tubular barrel main body, and a plurality of skirt portions separated from each other by a plurality of slits formed in a first end portion of the barrel main body in a lengthwise direction; and
a plunger comprising a sliding portion accommodated in the barrel main body and sliding along the lengthwise direction of the barrel, and a terminal contact portion extending from the sliding portion along the lengthwise direction and exposed beyond the skirt portion, wherein
the skirt portion comprises a skirt main body extending in the lengthwise direction of the barrel main body, and a skirt diameter-reducing portion curved reducing a diameter thereof in a fore-end area of the skirt main body in the lengthwise direction of the barrel and comprising a facing end portion to face a surface of the terminal contact portion, and
the sliding portion comprises a small diameter portion positioned in the skirt main body and having a first diameter, and a large diameter portion positioned in the barrel main body and having a second diameter larger than the first diameter.

2. The test probe of claim 1, wherein
the plunger comprises a slope contact portion provided between the sliding portion and the terminal contact portion to come into contact with an inner surface of the skirt diameter-reducing portion, and
the inner surface of the skirt diameter-reducing portion has a different linear slope from an outer surface of the slope contact portion.

3. The test probe of claim 1, wherein
the plunger comprises a slope contact portion provided between the sliding portion and the terminal contact portion to come into contact with an inner surface of the skirt diameter-reducing portion, and
the inner surface of the skirt diameter-reducing portion has a different curvature from an outer surface of the slope contact portion.

4. The test probe of claim 1, wherein
the plunger comprises a slope contact portion provided between the sliding portion and the terminal contact portion to come into contact with an inner surface of the skirt diameter-reducing portion,
one of the inner surface of the skirt diameter-reducing portion and an outer surface of the slope contact portion has a slope surface having a predetermined linear slope, and
the other one of the inner surface of the skirt diameter-reducing portion and the outer surface of the slope contact portion has a curved surface having a predetermined curvature.

5. The test probe of claim 1, wherein the terminal contact portion comprises a tapering portion, a diameter of which decreases in a direction toward the sliding portion, in at least a partial section thereof.

6. The test probe of claim 5, wherein the terminal contact portion comprises an extending bar extending from the tapering portion to an opposite side of the sliding portion, and having a uniform diameter.

7. The test probe of claim 1, wherein the terminal contact portion comprises a tip to come into contact with a terminal of a subject-to-be-tested, and a tapering portion having a diameter increasing in a direction from the tip toward the sliding portion.
